(19) United States
(12) Patent Application Publication
(10) Pub. No.: US 2024/0168390 A1
(43) Pub. Date: May 23, 2024

(54) MACHINE LEARNING FOR MASK OPTIMIZATION IN INVERSE LITHOGRAPHY TECHNOLOGIES

(71) Applicant: NVIDIA Corporation, Santa Clara, CA (US)

(72) Inventors: Haoyu Yang, Round Rock, TX (US); Haoxing Ren, Austin, TX (US)

(21) Appl. No.: 18/232,757

(22) Filed: Aug. 10, 2023

Related U.S. Application Data
(60) Provisional application No. 63/427,001, filed on Nov. 21, 2022.

(51) Int. Cl. G03F 7/00; G06T 7/00

(52) U.S. Cl. CPC G03F 7/706841; G03F 7/70683; G06T 7/0006; G06T 2207/20081; G06T 2207/20084; G06T 2207/30148

(57) ABSTRACT

In the semiconductor industry, lithography refers to a manufacturing process in which light is projected through a geometric design on a mask to illuminate the design on a semiconductor wafer. The wafer has a light-sensitive material (i.e. resist) on its surface which, when illuminated by the light, causes the design to be etched onto the wafer. However, this lithography process does not perfectly transfer the design to the wafer, particularly because some diffracted light will inevitably distort the pattern etched onto the wafer (i.e. the resist image). To address this issue in lithography, an inverse lithography technology has been developed which optimizes the mask to match the desired shapes on the wafer. The present disclosure improves current inverse lithography technology by employing machine learning for mask optimization.

### RELATED APPLICATION(S)

This application claims the benefit of U.S. Provisional Application No. 63/427,001 (Attorney Docket No. NVIDP1365+/22-AU-1498US01), titled “ILILT: Implicit Learning of Inverse Lithography Technologies” and filed Nov. 21, 2022, the entire contents of which is incorporated herein by reference.

### TECHNICAL FIELD

The present disclosure relates to inverse lithography processes.

### BACKGROUND

In the semiconductor industry, lithography refers to a manufacturing process in which light is projected through a geometric design on a mask to illuminate the design on a semiconductor wafer. The wafer has a light-sensitive material (i.e. resist) on its surface which, when illuminated by the light, causes the design to be etched onto the wafer. However, this lithography process does not perfectly transfer the design to the wafer, particularly because some diffracted light will inevitably distort the pattern etched onto the wafer (i.e. the resist image).

To address this issue in lithography, an inverse lithography technology has been developed which essentially reverse engineers, or optimizes, the mask to match the desired shapes on the wafer. Early inverse lithography technology involved numerical solvers that would begin with an initialized mask (usually the design pattern plus some assist features) and that would then iteratively perform forward and backward computation until convergence. The forward path would compute the resist image of the current mask and the backward path would apply the gradient of the resist image error to update the mask. Unfortunately, this early solution was slow as each forward pass was time consuming, and furthermore the results were often sub-optimal since they were highly dependent on the initial condition of the mask.

To address the limitations of numerical solvers, machine learning has been employed in more current solutions. Typically though, these current solutions still require significant intervention of numerical solvers. For example, one solution uses machine learning to compute the initial mask, but then relies on the forward/backward process of a numerical solver. Accordingly, current solutions also exhibit some of the same limitations of the early solutions, as they all rely to some extent on numerical solvers.

There is a need for addressing these issues and/or other issues associated with the prior art. For example, there is a need to use machine learning for mask optimization in inverse lithography technology.

### SUMMARY

A method, computer readable medium, and system are disclosed for using machine learning for mask optimization in inverse lithography technology. During an iteration of at least one iteration of an inverse lithography process, an input mask image and an input design image are processed utilizing a machine learning model to predict an output mask image, and the output mask image is output.

### BRIEF DESCRIPTION OF THE DRAWINGS

FIG. 1 illustrates a method for using machine learning for mask optimization in inverse lithography technology, in accordance with an embodiment.

FIG. 2 illustrates a system for using machine learning for mask optimization in inverse lithography technology, in accordance with an embodiment.

FIG. 3 illustrates a pipeline of the machine learning model in the system of FIG. 2, in accordance with an embodiment.

FIG. 4 illustrates an unrolled view of the pipeline of FIG. 3A, in accordance with an embodiment.

FIG. 5 illustrates an algorithm for training the machine learning model in the system of FIG. 2, in accordance with an embodiment.

FIG. 6A illustrates inference and/or training logic, according to at least one embodiment;

FIG. 6B illustrates inference and/or training logic, according to at least one embodiment;

FIG. 7 illustrates training and deployment of a neural network, according to at least one embodiment;

FIG. 8 illustrates an example data center system, according to at least one embodiment.

### DETAILED DESCRIPTION

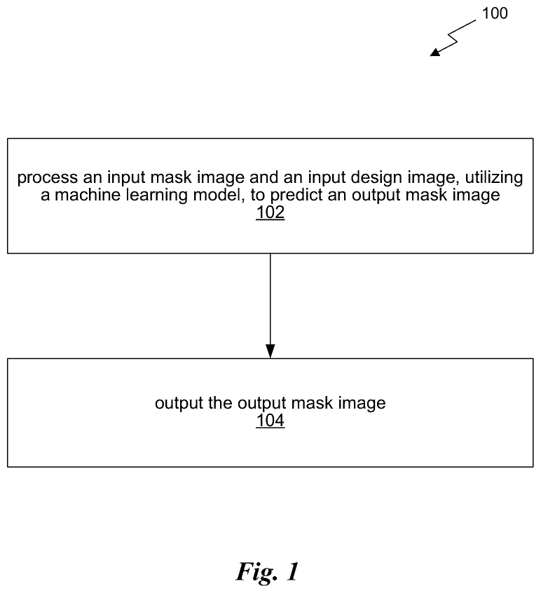

FIG. 1 illustrates a method for using machine learning for mask optimization in inverse lithography technology, in accordance with an embodiment. The method 100 may be performed by a device, which may be comprised of a processing unit, a program, custom circuitry, or a combination thereof, in an embodiment. In another embodiment a system comprised of a non-transitory memory storage comprising instructions, and one or more processors in communication with the memory, may execute the instructions to perform the method 100. In another embodiment, a non-transitory computer-readable media may store computer instructions which when executed by one or more processors of a device cause the device to perform the method 100.

The method 100 may be performed during an iteration of an inverse lithography process. The inverse lithography process refers to a process of computing a mask for a target pattern to be etched onto a semiconductor wafer. The inverse lithography process is employed to account for an imperfect design-to-wafer transfer (e.g. due to diffracted light distorting the design when illuminated on the wafer). For example, the mask may be computed such that, when used in a lithography process to etch a pattern onto the semiconductor wafer, the etched pattern matches the target pattern as closely as possible.

The inverse lithography process may include a single iteration, in an embodiment, or a plurality of iterations, in another embodiment. The method 100 may be repeated for each iteration of the inverse lithography process. In general, each iteration may function to generate a more refined mask for the target pattern. For example, over each iteration the mask may be increasingly optimized for the target pattern. The inverse lithography process may target a defined error (i.e. a minimized threshold difference from the target pattern), in an embodiment, and accordingly may iterate until the defined (minimized) error of the mask to the target pattern is achieved. In another embodiment, the inverse lithography process may include a predefined number of iterations. As described herein, the inverse lithography process may predict an optimized mask image for a given (input) design image.

With regard to an iteration of the inverse lithography process, and in particular with regard to the method 100, in operation 102, an input mask image and an input design image are processed, utilizing a machine learning model, to predict an output mask image. The input mask image refers to an image of a prior computed mask that is input to the machine learning model. The mask, sometimes also referred to as a photomask or a photolithography mask, is a physical component (e.g. plate) having a geometric design through which light can be transmitted.

In an embodiment where the current iteration of the inverse lithography process is an initial (i.e. first) iteration of the process, the input mask image may be an initialized mask image. In an embodiment where the current iteration of the inverse lithography process is a second or later iteration of the process, the input mask image may be that which has been computed during a prior iteration of the process. For example, as described in detail below, this prior computed input mask image may be an output mask image predicted during a prior iteration of the process.

Also with respect to the present description, the input design image refers to an image of a design that is input to the machine learning model. The design is a targeted pattern to be etched onto a semiconductor wafer. Further, the output mask image that is predicted by the machine learning model refers to an image of a mask that is output (i.e. predicted) by the machine learning model from the input mask image and the input design image. In an embodiment, the output mask image is a refinement, or optimization, of the input mask image targeted towards the input design image.

The machine learning model is a model trained using machine learning to predict a mask image from a given mask image and a given design image. In an embodiment, the machine learning model may be an implicit layer. In an embodiment, the machine learning model may be trained using, or over, a predefined number of iterations. In an embodiment, the machine learning model may be trained using back-propagation through the predefined number of iterations. In an embodiment, the machine learning model may be trained using a ground truth optimized mask.

In an embodiment, an input resist image may also be processed by the machine learning model to predict the output mask image. The input resist image refers to an image of a resist that is input to the machine learning model. In an embodiment, the input resist image is generated, or computed, as a function of the input mask image. In an embodiment, the input resist image may be generated by a forward lithography estimator. In various embodiments, the forward lithography estimator may be a second machine learning model, an existing physics model, or a pretrained function.

Returning to the iteration of the inverse lithography process, in operation 104, the output mask image is output. As described above, the output mask image predicted by the machine learning model may be output to a next iteration of the inverse lithography process. On the other hand, when the current iteration of the inverse lithography process is a final iteration of the process, then the output mask image may be the final output of the inverse lithography process. This final output may be a mask optimized for the given design. In turn, this mask may be used during a lithography process to etch the given design on a semiconductor wafer.

### Exemplary Implementation of the Method 100

In an embodiment, the method 100 may be implemented in the context of manufacturing a semiconductor device according to an original design image. With respect to this embodiment, the implementation may include receiving the original design image (e.g. an input design image with a target pattern), defining (e.g. initializing) a mask image for the original design image, providing the mask image and the original design image as an initial input to an inverse lithography machine learning model, at least two times iterating the steps of: the inverse lithography machine learning model generating from its current input a current output mask image that is optimized to the original design image, and the inverse lithography machine learning model outputting the current output mask image, wherein for each iteration of the steps prior to a final iteration of the steps, the current output mask image is output for use along with the original design image as a next input to the inverse lithography machine learning model, and using a final current output mask image (i.e. the current output mask image resulting from the final iteration of the steps) to perform lithography in physically manufacturing the semiconductor device.

Further embodiments will now be provided in the description of the subsequent figures. It should be noted that the embodiments disclosed herein with reference to the method 100 of FIG. 1 may apply to and/or be used in combination with any of the embodiments of the remaining figures below.

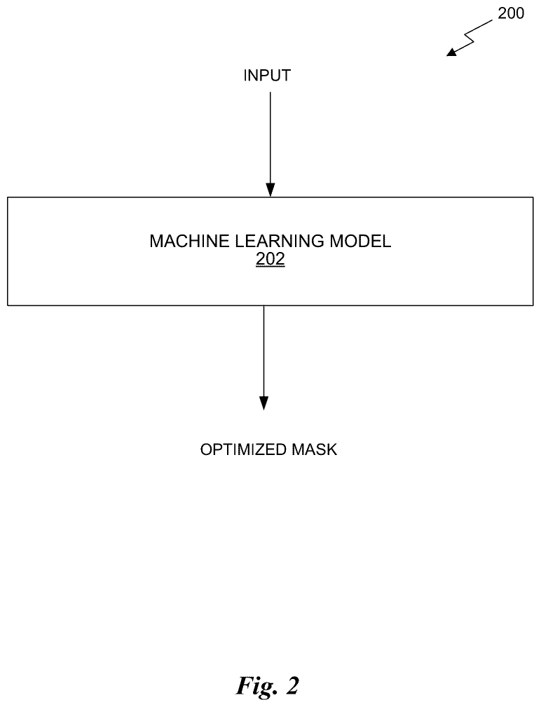

FIG. 2 illustrates a system 200 for using machine learning for mask optimization in inverse lithography technology, in accordance with an embodiment. The system 200 may be implemented to perform the method 100 of FIG. 1, in an embodiment. Of course, however, the system 200 may be implemented in any desired context. The definitions and embodiments described above may equally apply to the description of the present embodiment.

As shown, input is provided to an machine learning model 202. The machine learning model 202 executes on a computing device (e.g. server). In an embodiment, the machine learning model 202 may execute in a cloud. The machine learning model 202 is trained to predict a mask image for a target design, as described in more detail below.

The input may be received from an application. In an embodiment, the application may execute on the same computing device on which the machine learning model 202 executes. In another embodiment, the application may execute on a remote computing device, such that the machine learning model 202 may receive the input from the application via a network.

In the present embodiment, the input includes at least a mask image and a design image. In an embodiment, the input further includes a resist image generated from the mask image. The machine learning model 202 processes the input to predict a mask image from the input. The predicted mask image may be refined from the input mask image.

The machine learning model 202 outputs the predicted mask image. The machine learning model 202 may output the predicted mask image for a next iteration of processing by the machine learning model 202. In another embodiment, the machine learning model 202 may output the predicted mask image as a final optimized mask for the given design. Another system implementing a lithography process may then use the final optimized mask.

In the further embodiments described below, the following notations will be referenced:
Mₜ: Mask image at optimization time stamp t
Zₜ: Resist image of Mₜ
Z*: Target design image
M*: Optimized mask for Z*
J: Jacobian matrix
∥-∥_{F}: The Frobenius norm of a matrix
fₒ: Function of optical modeling
fᵣ: Function of resist modeling
f_{d}: Function measuring the error between a resist image and the design

### Machine Learning Model as an Implicit Layer

In an embodiment where the machine learning model 202 is an implicit layer, the implicit layer may be defined as finding M in accordance with Equation 1.

f(M,Z*)=f_{d}(fᵣ(fₒ(M)),Z*=ϵ Equation 1

where ϵ is some minimum value that can be achieved for Equation 1.

Because Equation 1 is a composite of a group of non-linear functions, which can be hard to be solved explicitly, it may be assumed that Equation 1 has a solution M* that follows the form of Equation 2.

M*=g(M*,Z*), Equation 2

which yields a fixed-point layer representations for the machine learning model 202.

Equation 2 can then be solved from a weight-tied approach, per Equations 3 and 4.

$${M}_{t + 1} = g ( {M}_{t} , {Z}^{*} , w ) , \qquad Equation 3$$

$$t = 1 , 2 , … ,$$

$${lim}_{t \to ∞} {M}_{t} = {lim}_{t \to ∞} g ( {M}_{t} , {Z}^{*} , w ) = g ( {M}^{*} , {Z}^{*} , w ) = {M}^{*} \qquad Equation 4$$

To ground the machine learning model 202, a lithograph estimator may be included in g, such that Equation 3 may be rewritten to Equation 5.

Mₜ₊₁=g(Mₜ,Zₜ,Z*,w),t=1,2, . . . , Equation 5

where Zₜ=gₗ(Mₜ,wₗ) is the resist image of Mₜ at time stamp t and gₗ is some forward lithography estimator. Equation 5 formulates the core of a reverse lithography process framework. A virtue of Equation 5 is the embedded condition of the lithography estimator that implicitly tells g the physical meaning of each step in the process.

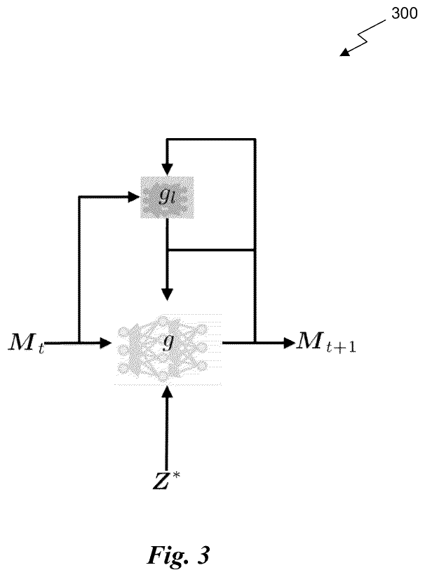

FIG. 3 illustrates a pipeline 300 of the machine learning model 202 in the system 200 of FIG. 2, in accordance with an embodiment. The pipeline 300 may therefor be implemented in the context of the machine learning model 202 of FIG. 2, in an embodiment. The definitions and embodiments described above may equally apply to the description of the present embodiment.

The illustrated pipeline 300 follows the basic structure described in Equation 5, which includes the specifically designed lithograph path gi. At time stamp t, there are three inputs going into g, which are Mₜ, Z* and Zₜ, and produce Mₜ₊₁. Zₜ is obtained by feeding Mₜ into some lithography estimator.

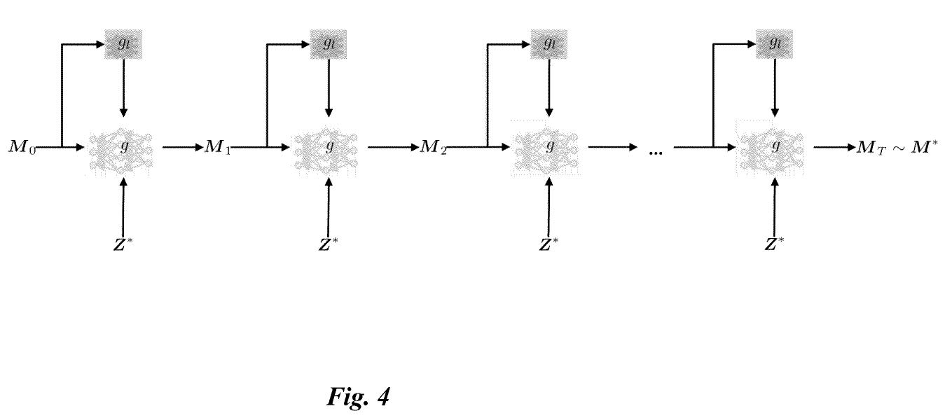

This process can also be unrolled until equilibrium status, as in FIG. 4. Theoretically, the unrolling depth could reach infinity, allowing higher level feature abstraction and temporal feature learning. However, based on specific hardware limitations, only a fixed unrolling depth may be allowed.

The major network g will gain the knowledge on how good the mask is (to achieve the given design) at the current time stamp. This feature enables automatic learning of fixed-point iteration.

### Machine Learning Model Training—an Embodiment

As disclosed above, Equation 5 defines a weight-tied fixed-point model representing the machine learning model 202 of FIG. 2. The training architecture described herein can solve this model efficiently and effectively.

During training, the model is unrolled to a fixed depth T and the final output M T is trained towards a ground truth mask M*. In other words, the model is trained over a predefined number of iterations, per Equation 6.

$${min}_{w , {w}_{l}} l = {‖ {M}_{T} - {M}^{*} ‖}_{F}^{2} , \qquad Equation 6$$

$$s . t . {M}_{t + 1} = g ( {M}_{t} , {Z}_{t} , {Z}^{*} , w ) , t = 0 , 1 , … , T - 1 ,$$

$${Z}_{t} = {g}_{l} ( {M}_{t} , {w}_{l} ) , t = 0 , 1 , … , T$$

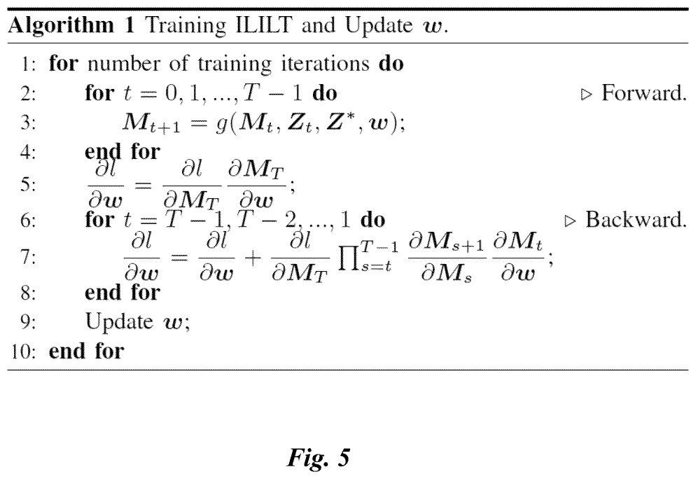

Solving Equation 6 is straightforward through back-propagation through time (BPTT). w is used as an example and the Algorithm 1 in FIG. 5 shows how w is updated during training. In various embodiments, gi can be a pretrained function or a real lithography model. Therefore we do not discuss the update of wₗ. Note that the key steps of Algorithm 1 is the gradient computation along different time stamps (lines 5-8) that are computed following the chain rule. Once the model is trained, the optimized mask is able to be fetched at time stamp T in the inference sequence.

### Machine Learning

Deep neural networks (DNNs), including deep learning models, developed on processors have been used for diverse use cases, from self-driving cars to faster drug development, from automatic image captioning in online image databases to smart real-time language translation in video chat applications. Deep learning is a technique that models the neural learning process of the human brain, continually learning, continually getting smarter, and delivering more accurate results more quickly over time. A child is initially taught by an adult to correctly identify and classify various shapes, eventually being able to identify shapes without any coaching. Similarly, a deep learning or neural learning system needs to be trained in object recognition and classification for it get smarter and more efficient at identifying basic objects, occluded objects, etc., while also assigning context to objects.

At the simplest level, neurons in the human brain look at various inputs that are received, importance levels are assigned to each of these inputs, and output is passed on to other neurons to act upon. An artificial neuron or perceptron is the most basic model of a neural network. In one example, a perceptron may receive one or more inputs that represent various features of an object that the perceptron is being trained to recognize and classify, and each of these features is assigned a certain weight based on the importance of that feature in defining the shape of an object.

A deep neural network (DNN) model includes multiple layers of many connected nodes (e.g., perceptrons, Boltzmann machines, radial basis functions, convolutional layers, etc.) that can be trained with enormous amounts of input data to quickly solve complex problems with high accuracy. In one example, a first layer of the DNN model breaks down an input image of an automobile into various sections and looks for basic patterns such as lines and angles. The second layer assembles the lines to look for higher level patterns such as wheels, windshields, and mirrors. The next layer identifies the type of vehicle, and the final few layers generate a label for the input image, identifying the model of a specific automobile brand.

Once the DNN is trained, the DNN can be deployed and used to identify and classify objects or patterns in a process known as inference. Examples of inference (the process through which a DNN extracts useful information from a given input) include identifying handwritten numbers on checks deposited into ATM machines, identifying images of friends in photos, delivering movie recommendations to over fifty million users, identifying and classifying different types of automobiles, pedestrians, and road hazards in driverless cars, or translating human speech in real-time.

During training, data flows through the DNN in a forward propagation phase until a prediction is produced that indicates a label corresponding to the input. If the neural network does not correctly label the input, then errors between the correct label and the predicted label are analyzed, and the weights are adjusted for each feature during a backward propagation phase until the DNN correctly labels the input and other inputs in a training dataset. Training complex neural networks requires massive amounts of parallel computing performance, including floating-point multiplications and additions. Inferencing is less compute-intensive than training, being a latency-sensitive process where a trained neural network is applied to new inputs it has not seen before to classify images, translate speech, and generally infer new information.

### Inference and Training Logic

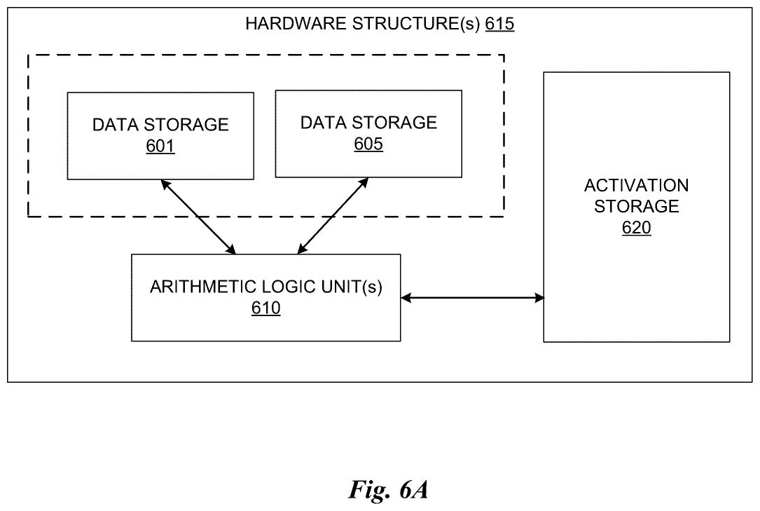

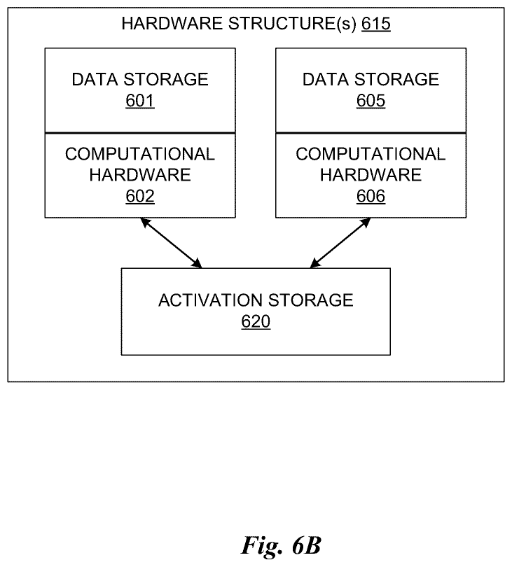

As noted above, a deep learning or neural learning system needs to be trained to generate inferences from input data. Details regarding inference and/or training logic 615 for a deep learning or neural learning system are provided below in conjunction with FIGS. 6A and/or 6B.

In at least one embodiment, inference and/or training logic 615 may include, without limitation, a data storage 601 to store forward and/or output weight and/or input/output data corresponding to neurons or layers of a neural network trained and/or used for inferencing in aspects of one or more embodiments. In at least one embodiment data storage 601 stores weight parameters and/or input/output data of each layer of a neural network trained or used in conjunction with one or more embodiments during forward propagation of input/output data and/or weight parameters during training and/or inferencing using aspects of one or more embodiments. In at least one embodiment, any portion of data storage 601 may be included with other on-chip or off-chip data storage, including a processor's L1, L2, or L3 cache or system memory.

In at least one embodiment, any portion of data storage 601 may be internal or external to one or more processors or other hardware logic devices or circuits. In at least one embodiment, data storage 601 may be cache memory, dynamic randomly addressable memory (“DRAM”), static randomly addressable memory (“SRAM”), non-volatile memory (e.g., Flash memory), or other storage. In at least one embodiment, choice of whether data storage 601 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors.

In at least one embodiment, inference and/or training logic 615 may include, without limitation, a data storage 605 to store backward and/or output weight and/or input/output data corresponding to neurons or layers of a neural network trained and/or used for inferencing in aspects of one or more embodiments. In at least one embodiment, data storage 605 stores weight parameters and/or input/output data of each layer of a neural network trained or used in conjunction with one or more embodiments during backward propagation of input/output data and/or weight parameters during training and/or inferencing using aspects of one or more embodiments. In at least one embodiment, any portion of data storage 605 may be included with other on-chip or off-chip data storage, including a processor's L1, L2, or L3 cache or system memory. In at least one embodiment, any portion of data storage 605 may be internal or external to on one or more processors or other hardware logic devices or circuits. In at least one embodiment, data storage 605 may be cache memory, DRAM, SRAM, non-volatile memory (e.g., Flash memory), or other storage. In at least one embodiment, choice of whether data storage 605 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors.

In at least one embodiment, data storage 601 and data storage 605 may be separate storage structures. In at least one embodiment, data storage 601 and data storage 605 may be same storage structure. In at least one embodiment, data storage 601 and data storage 605 may be partially same storage structure and partially separate storage structures. In at least one embodiment, any portion of data storage 601 and data storage 605 may be included with other on-chip or off-chip data storage, including a processor's L1, L2, or L3 cache or system memory.

In at least one embodiment, inference and/or training logic 615 may include, without limitation, one or more arithmetic logic unit(s) (“ALU(s)”) 610 to perform logical and/or mathematical operations based, at least in part on, or indicated by, training and/or inference code, result of which may result in activations (e.g., output values from layers or neurons within a neural network) stored in an activation storage 620 that are functions of input/output and/or weight parameter data stored in data storage 601 and/or data storage 605. In at least one embodiment, activations stored in activation storage 620 are generated according to linear algebraic and or matrix-based mathematics performed by ALU(s) 610 in response to performing instructions or other code, wherein weight values stored in data storage 605 and/or data 601 are used as operands along with other values, such as bias values, gradient information, momentum values, or other parameters or hyperparameters, any or all of which may be stored in data storage 605 or data storage 601 or another storage on or off-chip. In at least one embodiment, ALU(s) 610 are included within one or more processors or other hardware logic devices or circuits, whereas in another embodiment, ALU(s) 610 may be external to a processor or other hardware logic device or circuit that uses them (e.g., a co-processor). In at least one embodiment, ALUs 610 may be included within a processor's execution units or otherwise within a bank of ALUs accessible by a processor's execution units either within same processor or distributed between different processors of different types (e.g., central processing units, graphics processing units, fixed function units, etc.). In at least one embodiment, data storage 601, data storage 605, and activation storage 620 may be on same processor or other hardware logic device or circuit, whereas in another embodiment, they may be in different processors or other hardware logic devices or circuits, or some combination of same and different processors or other hardware logic devices or circuits. In at least one embodiment, any portion of activation storage 620 may be included with other on-chip or off-chip data storage, including a processor's L1, L2, or L3 cache or system memory. Furthermore, inferencing and/or training code may be stored with other code accessible to a processor or other hardware logic or circuit and fetched and/or processed using a processor's fetch, decode, scheduling, execution, retirement and/or other logical circuits.

In at least one embodiment, activation storage 620 may be cache memory, DRAM, SRAM, non-volatile memory (e.g., Flash memory), or other storage. In at least one embodiment, activation storage 620 may be completely or partially within or external to one or more processors or other logical circuits. In at least one embodiment, choice of whether activation storage 620 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors. In at least one embodiment, inference and/or training logic 615 illustrated in FIG. 6A may be used in conjunction with an application-specific integrated circuit (“ASIC”), such as Tensorflow® Processing Unit from Google, an inference processing unit (IPU) from Graphcore™, or a Nervana® (e.g., “Lake Crest”) processor from Intel Corp. In at least one embodiment, inference and/or training logic 615 illustrated in FIG. 6A may be used in conjunction with central processing unit (“CPU”) hardware, graphics processing unit (“GPU”) hardware or other hardware, such as field programmable gate arrays (“FPGAs”).

FIG. 6B illustrates inference and/or training logic 615, according to at least one embodiment. In at least one embodiment, inference and/or training logic 615 may include, without limitation, hardware logic in which computational resources are dedicated or otherwise exclusively used in conjunction with weight values or other information corresponding to one or more layers of neurons within a neural network. In at least one embodiment, inference and/or training logic 615 illustrated in FIG. 6B may be used in conjunction with an application-specific integrated circuit (ASIC), such as Tensorflow® Processing Unit from Google, an inference processing unit (IPU) from Graphcore™, or a Nervana® (e.g., “Lake Crest”) processor from Intel Corp. In at least one embodiment, inference and/or training logic 615 illustrated in FIG. 6B may be used in conjunction with central processing unit (CPU) hardware, graphics processing unit (GPU) hardware or other hardware, such as field programmable gate arrays (FPGAs). In at least one embodiment, inference and/or training logic 615 includes, without limitation, data storage 601 and data storage 605, which may be used to store weight values and/or other information, including bias values, gradient information, momentum values, and/or other parameter or hyperparameter information. In at least one embodiment illustrated in FIG. 6B, each of data storage 601 and data storage 605 is associated with a dedicated computational resource, such as computational hardware 602 and computational hardware 606, respectively. In at least one embodiment, each of computational hardware 606 comprises one or more ALUs that perform mathematical functions, such as linear algebraic functions, only on information stored in data storage 601 and data storage 605, respectively, result of which is stored in activation storage 620.

In at least one embodiment, each of data storage 601 and 605 and corresponding computational hardware 602 and 606, respectively, correspond to different layers of a neural network, such that resulting activation from one “storage/computational pair 601/602” of data storage 601 and computational hardware 602 is provided as an input to next “storage/computational pair 605/606” of data storage 605 and computational hardware 606, in order to mirror conceptual organization of a neural network. In at least one embodiment, each of storage/computational pairs 601/602 and 605/606 may correspond to more than one neural network layer. In at least one embodiment, additional storage/computation pairs (not shown) subsequent to or in parallel with storage computation pairs 601/602 and 605/606 may be included in inference and/or training logic 615.

### Neural Network Training and Deployment

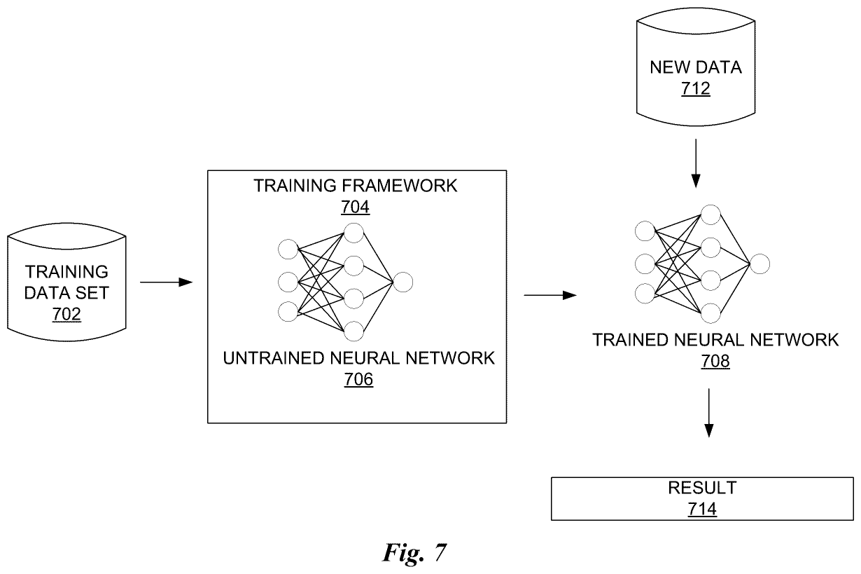

FIG. 7 illustrates another embodiment for training and deployment of a deep neural network. In at least one embodiment, untrained neural network 706 is trained using a training dataset 702. In at least one embodiment, training framework 704 is a PyTorch framework, whereas in other embodiments, training framework 704 is a Tensorflow, Boost, Caffe, Microsoft Cognitive Toolkit/CNTK, MXNet, Chainer, Keras, Deeplearning4j, or other training framework. In at least one embodiment training framework 704 trains an untrained neural network 706 and enables it to be trained using processing resources described herein to generate a trained neural network 708. In at least one embodiment, weights may be chosen randomly or by pre-training using a deep belief network. In at least one embodiment, training may be performed in either a supervised, partially supervised, or unsupervised manner.

In at least one embodiment, untrained neural network 706 is trained using supervised learning, wherein training dataset 702 includes an input paired with a desired output for an input, or where training dataset 702 includes input having known output and the output of the neural network is manually graded. In at least one embodiment, untrained neural network 706 is trained in a supervised manner processes inputs from training dataset 702 and compares resulting outputs against a set of expected or desired outputs. In at least one embodiment, errors are then propagated back through untrained neural network 706. In at least one embodiment, training framework 704 adjusts weights that control untrained neural network 706. In at least one embodiment, training framework 704 includes tools to monitor how well untrained neural network 706 is converging towards a model, such as trained neural network 708, suitable to generating correct answers, such as in result 714, based on known input data, such as new data 712. In at least one embodiment, training framework 704 trains untrained neural network 706 repeatedly while adjust weights to refine an output of untrained neural network 706 using a loss function and adjustment algorithm, such as stochastic gradient descent. In at least one embodiment, training framework 704 trains untrained neural network 706 until untrained neural network 706 achieves a desired accuracy. In at least one embodiment, trained neural network 708 can then be deployed to implement any number of machine learning operations.

In at least one embodiment, untrained neural network 706 is trained using unsupervised learning, wherein untrained neural network 706 attempts to train itself using unlabeled data. In at least one embodiment, unsupervised learning training dataset 702 will include input data without any associated output data or “ground truth” data. In at least one embodiment, untrained neural network 706 can learn groupings within training dataset 702 and can determine how individual inputs are related to untrained dataset 702. In at least one embodiment, unsupervised training can be used to generate a self-organizing map, which is a type of trained neural network 708 capable of performing operations useful in reducing dimensionality of new data 712. In at least one embodiment, unsupervised training can also be used to perform anomaly detection, which allows identification of data points in a new dataset 712 that deviate from normal patterns of new dataset 712.

In at least one embodiment, semi-supervised learning may be used, which is a technique in which in training dataset 702 includes a mix of labeled and unlabeled data. In at least one embodiment, training framework 704 may be used to perform incremental learning, such as through transferred learning techniques. In at least one embodiment, incremental learning enables trained neural network 708 to adapt to new data 712 without forgetting knowledge instilled within network during initial training.

### Data Center

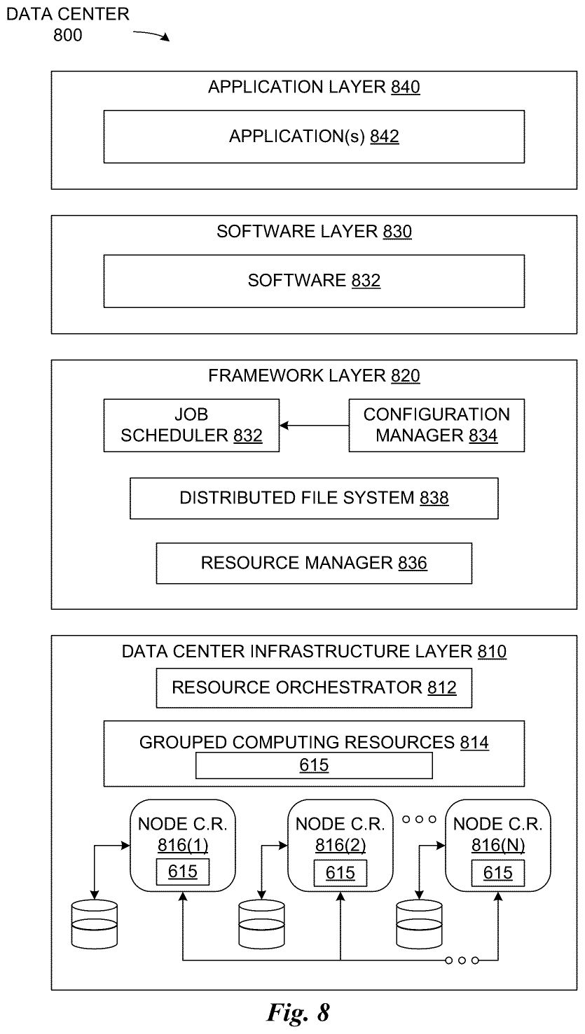

FIG. 8 illustrates an example data center 800, in which at least one embodiment may be used. In at least one embodiment, data center 800 includes a data center infrastructure layer 810, a framework layer 820, a software layer 830 and an application layer 840.

In at least one embodiment, as shown in FIG. 8, data center infrastructure layer 810 may include a resource orchestrator 812, grouped computing resources 814, and node computing resources (“node C.R.s”) 816(1)-816(N), where “N” represents any whole, positive integer. In at least one embodiment, node C.R.s 816(1)-816(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 816(1)-816(N) may be a server having one or more of above-mentioned computing resources.

In at least one embodiment, grouped computing resources 814 may include separate groupings of node C.R.s housed within one or more racks (not shown), or many racks housed in data centers at various geographical locations (also not shown). Separate groupings of node C.R.s within grouped computing resources 814 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 822 may configure or otherwise control one or more node C.R.s 816(1)-816(N) and/or grouped computing resources 814. In at least one embodiment, resource orchestrator 822 may include a software design infrastructure (“SDI”) management entity for data center 800. In at least one embodiment, resource orchestrator may include hardware, software or some combination thereof.

In at least one embodiment, as shown in FIG. 8, framework layer 820 includes a job scheduler 832, a configuration manager 834, a resource manager 836 and a distributed file system 838. In at least one embodiment, framework layer 820 may include a framework to support software 832 of software layer 830 and/or one or more application(s) 842 of application layer 840. In at least one embodiment, software 832 or application(s) 842 may respectively include web-based service software or applications, such as those provided by Amazon Web Services, Google Cloud and Microsoft Azure. In at least one embodiment, framework layer 820 may be, but is not limited to, a type of free and open-source software web application framework such as Apache Spark™ (hereinafter “Spark”) that may utilize distributed file system 838 for large-scale data processing (e.g., “big data”). In at least one embodiment, job scheduler 832 may include a Spark driver to facilitate scheduling of workloads supported by various layers of data center 800. In at least one embodiment, configuration manager 834 may be capable of configuring different layers such as software layer 830 and framework layer 820 including Spark and distributed file system 838 for supporting large-scale data processing. In at least one embodiment, resource manager 836 may be capable of managing clustered or grouped computing resources mapped to or allocated for support of distributed file system 838 and job scheduler 832. In at least one embodiment, clustered or grouped computing resources may include grouped computing resource 814 at data center infrastructure layer 810. In at least one embodiment, resource manager 836 may coordinate with resource orchestrator 812 to manage these mapped or allocated computing resources.

In at least one embodiment, software 832 included in software layer 830 may include software used by at least portions of node C.R.s 816(1)-816(N), grouped computing resources 814, and/or distributed file system 838 of framework layer 820. one or more types of software may include, but are not limited to, Internet web page search software, e-mail virus scan software, database software, and streaming video content software.

In at least one embodiment, application(s) 842 included in application layer 840 may include one or more types of applications used by at least portions of node C.R.s 816(1)-816(N), grouped computing resources 814, and/or distributed file system 838 of framework layer 820. one or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 834, resource manager 836, and resource orchestrator 812 may implement any number and type of self-modifying actions based on any amount and type of data acquired in any technically feasible fashion. In at least one embodiment, self-modifying actions may relieve a data center operator of data center 800 from making possibly bad configuration decisions and possibly avoiding underutilized and/or poor performing portions of a data center.

In at least one embodiment, data center 800 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 800. In at least one embodiment, trained machine learning models corresponding to one or more neural networks may be used to infer or predict information using resources described above with respect to data center 800 by using weight parameters calculated through one or more training techniques described herein.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 615 are used to perform inferencing and/or training operations associated with one or more embodiments. In at least one embodiment, inference and/or training logic 615 may be used in system FIG. 8 for inferencing or predicting operations based, at least in part, on weight parameters calculated using neural network training operations, neural network functions and/or architectures, or neural network use cases described herein.

As described herein with reference to FIGS. 1-5, a method, computer readable medium, and system are disclosed for using machine learning for mask optimization in inverse lithography technology. The machine learning model may be stored (partially or wholly) in one or both of data storage 601 and 605 in inference and/or training logic 615 as depicted in FIGS. 6A and 6B. Training and deployment of the machine learning may be performed as depicted in FIG. 7 and described herein. Distribution of the machine learning may be performed using one or more servers in a data center 800 as depicted in FIG. 8 and described herein.

What is claimed is:

1. A method comprising:
at a device, during an iteration of at least one iteration of an inverse lithography process:
processing an input mask image and an input design image, utilizing a machine learning model, to predict an output mask image; and
outputting the output mask image.

2. The method of claim 1, wherein the inverse lithography process includes a plurality of iterations.

3. The method of claim 2, wherein a number of iterations included in the plurality of iterations is predefined.

4. The method of claim 2, wherein for an initial iteration of the inverse lithography process, the input mask image is an initialized mask image.

5. The method of claim 4, wherein for each subsequent iteration of the inverse lithography process, the input mask image is the output mask image predicted during a prior iteration.

6. The method of claim 1, wherein during the iteration, the machine learning model further processes an input resist image.

7. The method of claim 6, wherein the input resist image is generated as a function of the input mask image.

8. The method of claim 6, wherein the input resist image is generated by a forward lithography estimator.

9. The method of claim 6, wherein the forward lithography estimator is a second machine learning model or an existing physics model.

10. The method of claim 6, wherein the forward lithography estimator is a pretrained function.

11. The method of claim 1, wherein the inverse lithography process predicts an optimized mask image for the input design image.

12. The method of claim 1, wherein the machine learning model is an implicit layer.

13. The method of claim 1, wherein the machine learning model is trained using a predefined number of iterations.

14. The method of claim 13, wherein the machine learning model is trained using back-propagation through the predefined number of iterations.

15. The method of claim 13, wherein the machine learning model is trained using a ground truth optimized mask.

16. A system, comprising:
a non-transitory memory storage comprising instructions; and
one or more processors in communication with the memory, wherein the one or more processors execute the instructions to perform an iteration of at least one iteration of an inverse lithography process, including during the iteration:
process an input mask image and an input design image, utilizing a machine learning model, to predict an output mask image; and
output the output mask image.

17. The system of claim 16, wherein the inverse lithography process includes a plurality of iterations.

18. The method of claim 17, wherein for an initial iteration of the inverse lithography process, the input mask image is an initialized mask image, and wherein for each subsequent iteration of the inverse lithography process the input mask image is the output mask image predicted during a prior iteration.

19. The method of claim 16, wherein the inverse lithography process predicts an optimized mask image for the input design image.

20. A non-transitory computer-readable media storing computer instructions which when executed by one or more processors of a device cause the device to perform an iteration of at least one iteration of an inverse lithography process, including during the iteration:
process an input mask image and an input design image, utilizing a machine learning model, to predict an output mask image; and
output the output mask image.

21. A method of manufacturing a semiconductor device according to an original design image, the method comprising:
receiving the original design image;
defining a mask image for the original design image;
providing the mask image and the original design image as an initial input to an inverse lithography machine learning model;
at least two times iterating the steps of:
the inverse lithography machine learning model generating from its current input a current output mask image that is optimized to the original design image, and
the inverse lithography machine learning model outputting the current output mask image,
wherein for each iteration of the steps prior to a final iteration of the steps, the current output mask image is output for use along with the original design image as a next input to the inverse lithography machine learning model; and
using a final current output mask image to perform lithography in physically manufacturing the semiconductor device.
